(19) United States
(12) Patent Application Publication
(10) Pub. No.: US 2008/0169803 A1
(43) Pub. Date: Jul. 17, 2008

(54) DEVICE TRANSFER SYSTEM

(75) Inventors: Seiji KUNINOBU, Tokyo (JP); Kazuhiko INAMURA, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: YOKOGAWA ELECTRIC CORPORATION, Tokyo (JP)

(21) Appl. No.: 12/013,022

(22) Filed: Jan. 11, 2008

(30) Foreign Application Priority Data
Jan. 12, 2007 (JP) 2007-004039

(51) Int. Cl. G01R 1/02

(52) U.S. Cl. 324/158.1

(57) ABSTRACT

The invention provides a device transfer system capable of lessening swaying of a movable body (handler), and simplifying the indexing mechanism. The device transfer system comprises a transfer means for transferring a device under test, held by a contact head, a test site for testing electrical characteristics of the device under test, and an indexing means for intermittently shifting the device under test, placed on a device tray, wherein the transfer means are made up such that two contact heads are concurrently and horizontally shifted in respective directions opposite to each other.

### FIELD OF THE INVENTION

The invention relates to a device transfer system for supplying a device under test so as to be tested at a test site, thereby housing the device under test after completion of the test, and in particular, to a device transfer system intended to lessen vibration occurring due to shifting of contact heads.

### BACKGROUND OF THE INVENTION

As for the related arts concerning a device transfer system, the following Patent documents are well known:
[Patent Document 1] JP 6-293434A
[Patent Document 2] JP 7-239367A
[Patent Document 3] JP 11-281704A

A makeup of a device (hereinafter referred to as an IC) transfer system according to the conventional technology, disclosed in JP-A 6-293434 among those Patent documents, is described hereinafter with reference to FIG. 3.

In FIG. 3, reference numeral 5 denotes a tester (a test site), 5A, 5B each denote an IC socket, 10 denotes an IC, 11 a supply stage, 12 a housing stage, 16 a transfer mechanism, 16A, 16B each denote an adsorption hand, and 16c, 16d each denote an adsorption pad.

Further, in FIG. 3, the supply stage 11 is disposed on a first column Y1, and is shifted in the y-axis direction. The supply stage 11 is provided with cavities 11A, 11B, disposed in a plurality of rows, respectively. When the IC 10 is placed over the cavities 11A, 11B, a posture of the IC 10 is corrected. The housing stage 12 is disposed on a second column Y2, and is shifted in the y-axis direction. The housing stage 12 is provided with cavities 12A, 12B, disposed in a plurality of rows, respectively. When the IC 10 is placed over the cavities 12A, 12B, the posture of the IC 10 is corrected.

In FIG. 3, the cavities 11A, 11B each are the same in shape as the respective cavities 12A, 12B, and a groove in the shape of a rectangle slightly larger than an outer shape of the IC 10 is formed in each of the cavities 11A, 11B, 12A, and 12B.

Since inlets of the respective grooves are provided with a slope, the IC 10 is guided by the slope to thereby correct the posture thereof. If positioning of the IC 10 is implemented with precision, this will facilitate positioning of the supply stage 11 against the IC sockets 5A, 5B, as described later. Or this will facilitate transfer of the IC from the housing stage 12 to the next process step.

The tester (test site) 5 is provided with the IC sockets 5A, 5B, and the IC sockets 5A, 5B are disposed on a column YM at a distance equal from the first column Y1, and the second column Y2, respectively. An interlinear distance between the IC sockets 5A, 5B is identical to that between the cavities 11A, 11B as well as that between the cavities 12A, 12B.

The transfer mechanism 16 is provided with the adsorption hands 16A, 16B, and the adsorption pads 16C, 16D. The adsorption hands 16A, 16B each incorporate an adsorption pad capable of adsorbing an upper face of the IC 10 by the agency of a negative pressure, and the periphery of the adsorption pad is fitted with a press-contact member coming into contact with leads of the IC 10. When the adsorption hands 16A, 16B, in such a state as to adsorb, and hold the IC 10, are pressed down onto the IC sockets 5A and 5B, the press-contact member will cause the leads of the IC 10 to press respective contacts of the IC sockets 5A and 5B into contact therewith. The adsorption pads 16C, 16D each are the same adsorption pad as is incorporated in the adsorption hands 16A, 16B, respectively.

In FIG. 3, the adsorption hands 16A, 16B, and the adsorption pads 16C, 16D ascend and descend in the direction of the z-axis. An inter-column distance between the adsorption hands 16A, 16B, and the adsorption pads 16C, 16D is identical to a distance between the first column Y1, and the column YM while the interlinear distance between the adsorption hands 16A, 16B, and that between the adsorption pads 16C, 16D are each identical to the interlinear distance between the IC sockets 5A, 5B. The transfer mechanism 16 is shifted in the x-axis direction by housing the adsorption hands 16A, 16B integrally with the adsorption pads 16C, 16D, respectively.

Now, operation of the device transfer system shown in FIG. 3 is described hereinafter with reference to FIGS. 4 to 6, which are views showing various operation states, respectively. FIGS. 4 to 6 each are a front elevation of the device transfer system shown in FIG. 3. In FIG. 4, reference numeral 60 denotes a movable body, and a cylinder 16E and a cylinder 16F are attached to the movable body 60. When the cylinder 16E is driven, the adsorption hands 16A, 16B each are guided by a linear guide fitted to a sidewall of the movable body 60 to thereby ascend and descend. When the cylinder 16F is driven, the adsorption pads 16C, 16D each are guided by a linear guide fitted to another sidewall of the movable body 60 to thereby ascend and descend. A motor 60A is linked with a ball thread, and the ball thread is joined with a ball nut attached to the motor 60A. Upon rotation of the motor 60A, the motor 60A causes the movable body 60 to shift in the x-axis direction.

With the movable body 60 in a state shown in FIG. 4(a), the ICs 10 are transferred to the IC sockets 5A, 5B by the adsorption hands 16A, 16B, respectively, and the next ICs 10 are standing by at the supply stage 11. Testing of the ICs 10 over the IC sockets 5A, 5B has been completed.

The movable body 60 in the state shown in FIG. 4(a) is shifted toward the supply stage 11 to rest in a state shown in FIG. 4(b). In the state shown in FIG. 4(b), the adsorption hands 16A, 16B are positioned over the supply stage 11 while the adsorption pads 16C, 16D are positioned over the IC sockets 5A, 5B.

From the state shown in FIG. 4(b), the adsorption hands 16A, 16B as well as the adsorption pads 16C, 16D descend so as to rest in a state shown in FIG. 5(a). In the state shown in FIG. 5(a), the adsorption hands 16A, 16B adsorb the ICs 10 over the supply stage 11, respectively, while the adsorption pads 16C, 16D adsorb the ICs 10 over the IC sockets 5A, 5B, respectively. From the state shown in FIG. 5(a), the adsorption hands 16A, 16B as well as the adsorption pads 16C, 16D adsorb and hold the ICs 10, respectively, thereby ascending so as to be in a state shown in FIG. 5(b).

The movable body 60 in the state shown in FIG. 5(b) is shifted toward the housing stage 12 to rest in a state shown in FIG. 6(a). In the state shown in FIG. 6(a), the adsorption hands 16A, 16B are positioned over the IC sockets 5A, 5B, respectively, while the adsorption pads 16C, 16D are positioned over the housing stage 12.

From the state shown in FIG. 6(a), the adsorption hands 16A, 16B as well as the adsorption pads 16C, 16D descend so as to rest in a state shown in FIG. 6(b). In FIG. 6(b), the adsorption hands 16A, 16B cause the ICs 10 to be pressed into contact with the IC sockets 5A and 5B, respectively, while the adsorption pads 16C, 16D release the ICs 10 onto the cavities 12A, 12B of the housing stage 12, respectively.

In the state shown in FIG. 6(b), testing of the ICs 10 over the IC sockets 5A and 5B, respectively, is completed, the ICs 10 over the housing stage 12 are transferred to the next process step, and the next ICs 10 are transferred to the supply stage 11, whereupon the operation reverts to the state shown in FIG. 4(a), thereby completing a series of transfer cycle steps.

### SUMMARY OF THE INVENTION

If attention is focused only on movements of the devices held by respective contact heads of the transfer mechanism, shown in FIGS. 4 to 6, respectively, the movements of the devices are illustrated as shown in FIG. 7. More specifically, the respective contact heads adsorbed to the adsorption hands, and the adsorption pads, attached to the movable body 60, are concurrently shifted in the x-axis direction, indicated by an arrow A or B.

Thus, there are disposed the supply stage for supplying the ICs to the respective contact heads, and the housing stage for housing the ICs therein, with a test site 25 sandwiched therebetween. The adsorption hands are shifted between the supply stage, and the IC sockets, and concurrently, the adsorption pads shuttle to and fro between the IC sockets, and the housing stage.

Now, a problem has been encountered in that when two contact heads concurrently undergo a horizontal shift in the same direction upon indexing of the contact heads, respective counterforces of force, necessary for acceleration of the two contact heads, will act on a handler to thereby cause the movable body (the handler) to sway, so that adverse effects will be exerted on connection with the tester. Furthermore, two spots are required for use as a stage for supplying the ICs to the contact heads, and a stage for receiving the ICs from the contact heads, respectively, so that a structure of an indexing mechanism increases in size, thereby resulting in a problem of an increase in cost.

In order to solve the problem with the conventional technology described, the invention has been developed, and it is therefore an object of the invention to provide a device transfer system capable of lessening swaying of the movable body (the handler), and simplifying the indexing mechanism to thereby attaining reduction in cost.

In order to achieve the object, the invention provides in its first aspect a device transfer system comprising a transfer means for transferring a device under test, held by a contact head, a test site for testing electrical characteristics of the device under test, and an indexing means for intermittently shifting the device under test, placed on a device tray, wherein the transfer means are made up such that two contact heads are concurrently and horizontally shifted in respective directions opposite to each other.

With those features, the two contact heads are preferably made up so as to differ in height from each other, thereby enabling the two contact heads to pass by each other.

Further, the contact heads making up the transfer means are preferably configured so as to shuttle to and fro between the device tray including an empty tray, and a test site disposed in the vicinity of the device tray while passing by each other in the respective directions opposite to each other.

As is evident from the foregoing description, with the invention, the transfer means are made up such that the two contact heads differ in height from each other so as to be able to pass by each other, thereby allowing the two contact heads to concurrently and horizontally shift in the respective directions opposite to each other, and the contact heads making up the transfer means are configured so as to shuttle to and fro between the device tray including the empty tray, and the test site disposed in the vicinity of the device tray while passing by each other in the respective directions opposite to each other, so that respective counterforces of force, necessary for acceleration of the two contact heads, act in directions opposite to each other, thereby canceling out each other. As a result, it is possible to prevent swaying of the transfer means without exerting adverse effects on connection with the tester.

Furthermore, as it need only be sufficient to provide one column of the device trays for supplying the contact heads with the device, and for housing the devices, the structure of the indexing mechanism can be rendered compact and low in cost.

### BRIEF DESCRIPTION OF THE DRAWINGS

FIGS. 1A to 1F each are a block diagram of the principal parts of a device transfer system according to one embodiment of the invention, showing respective movements of transfer bodies;

FIG. 2 is a schematic illustration showing movements of devices held by respective contact heads;

FIG. 3 is a block diagram of the principal parts of a conventional device transfer system;

FIG. 4 is a schematic illustration showing operation of the conventional device transfer system;

FIG. 5 is a schematic illustration showing another operation of the conventional device transfer system;

FIG. 6 is a schematic illustration showing still another operation of the conventional device transfer system; and

FIG. 7 is a schematic illustration showing movements of devices held by conventional contact heads, respectively.

### PREFERRED EMBODIMENTS OF THE INVENTION

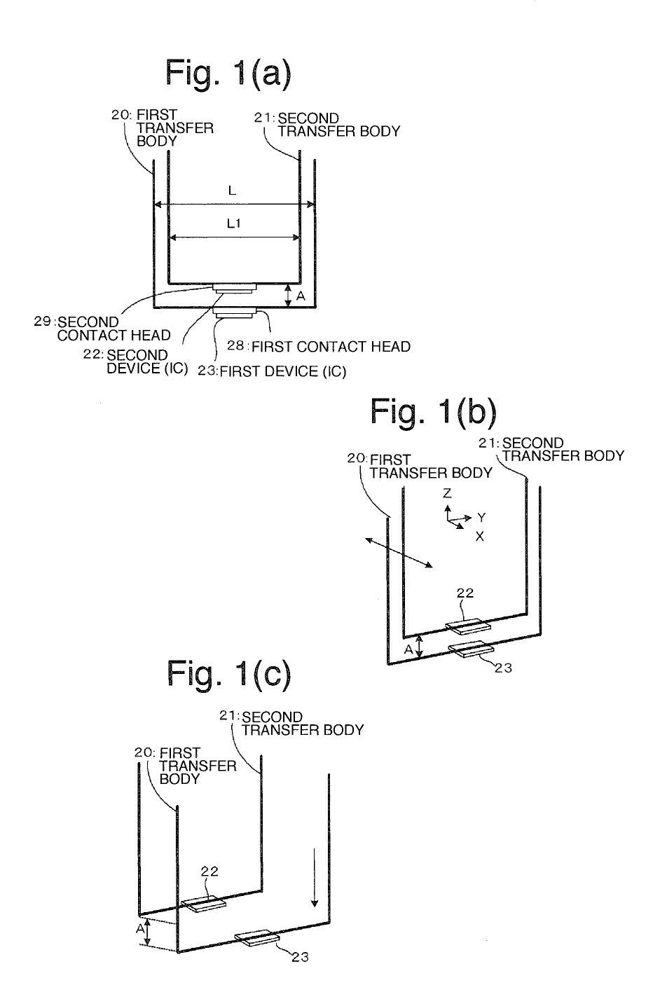

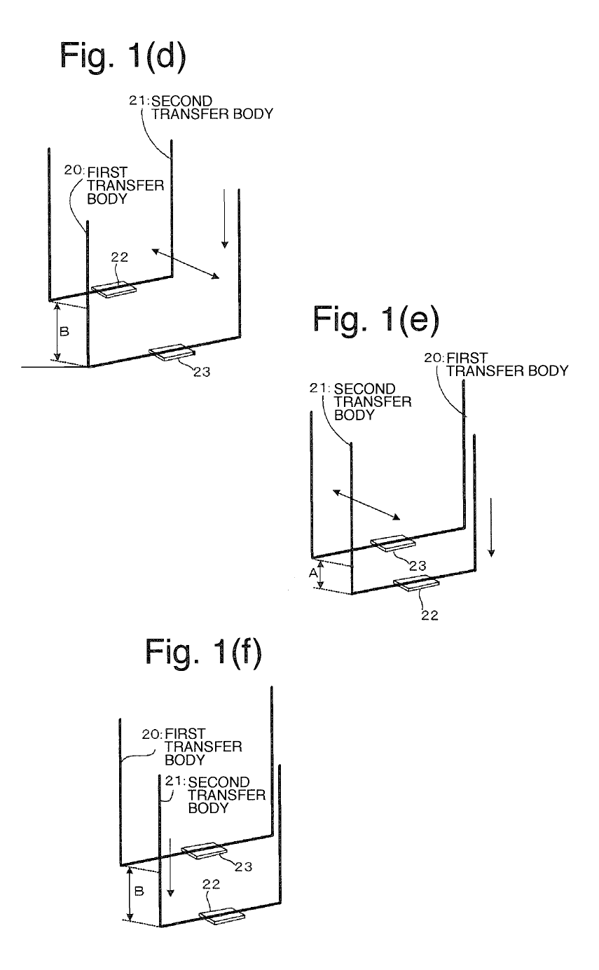

An embodiment of the invention is described hereinafter with reference to the accompanying drawings. FIG. 1(a) is a front elevation of the principal parts of a device transfer means according to one embodiment of the invention, and FIGS. 1B to 1F each are a perspective view showing operation of the transfer means.

In those figures, first and second transfer bodies 20, 21 each are driven in the x-axis direction and the y-axis direction, respectively, among the respective directions of the x-axis, y-axis, and z-axis, shown in FIG. 1, by drive means (not shown), and control means (not shown).

First and second contact heads 28, 29 each are provided with adsorption means (not shown in the figure) for holding first and second devices 23, 22, respectively, and so forth. Further, the first transfer body 20 for transferring the first contact head 28 is formed such that a width L of the first transfer body 20 is greater than a with L1 of the second transfer body 21 for transferring the second contact head 29, so that the first and second transfer bodies 20, 21 are configured so as to be able to pass by each other.

A test site (IC sockets) and device trays are disposed in the x-axis direction of the first and second transfer bodies 20, 21, respectively, although not shown in the figure. Further, in FIGS. 1B to 1F, the respective contact heads are not shown.

FIGS. 1A, 1B each show a state where the first and second contact heads 28, 29 attached to the first and second transfer bodies 20, 21, respectively, in such a state as to hold the first and second devices 23, 22, respectively, are in the middle of transfer in directions toward the distal end, and the proximal end, in the plane, respectively, with a height difference A kept therebetween. It is assumed that in this state, testing of the first device 23 held by the first contact head of the first transfer body 20 has been completed, and the second device 22 held by the second contact head of the second transfer body 21 is in as-untested state.

FIG. 1(c) shows a state where the first transfer body 20 is shifted to over the test site (the IC sockets), and the second transfer body 21 is shifted to over the device tray with the height difference A kept therebetween.

Then, as shown in FIG. 1(d), the first and second transfer bodies 20, 21 concurrently start descending and with the first and second transfer bodies 20, 21, in as-descended state so as to have a height difference B greater than the height difference A, the second device 22 that is yet-to-be tested comes into contact with the test site, whereupon testing is conducted.

Meanwhile, the first device 23 that has already been tested is placed on an empty device tray of the device trays, to be followed by slight ascent of the contact head, and in the meantime, the device tray on which the device is placed is shifted by one at a time. Subsequently, the contact head descends to hold the device yet to be tested, and the second transfer body 21 ascends to a predetermined position, thereby reverting to the state shown in FIG. 1(c).

Next, as shown in FIG. 1(e), the first and second transfer bodies 20, 21 are shifted in respective directions opposite to each other, along the x-axis, with the height difference A kept therebetween, and the second device 22 in as-untested state is shifted to over the test site while the first device 23 that has already been tested is shifted over the device tray.

Subsequently, the first and second transfer bodies 20, 21, in this state, concurrently start descending, and with the first and second transfer bodies 20, 21, in as-descended state to have the height difference B greater than the height difference A, the second device 22 in as-untested state comes into contact with the test site, whereupon testing is conducted. The first device 23 that has already been tested is placed on the empty device tray of the device trays, to be followed by slight ascent of the contact head, as previously described, and in the meantime, the device trays is shifted by one. Subsequently, the contact head descends to hold the device in as-untested state, and the first and second transfer bodies 20, 21 ascend to the predetermined position, thereby reverting to the respective states shown in FIGS. 1A and 1B.

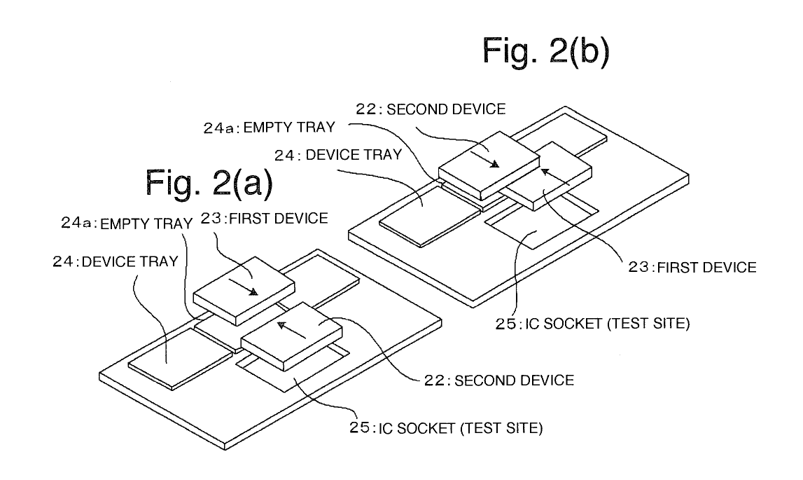

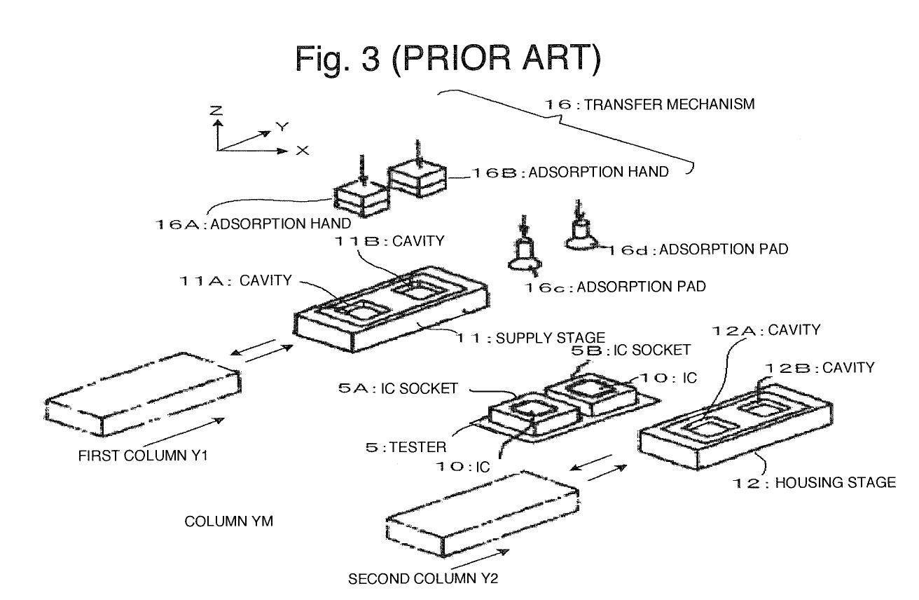

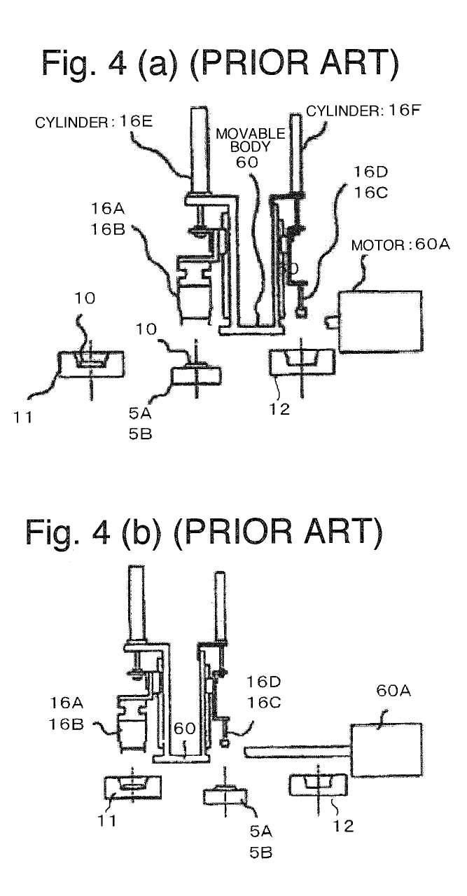

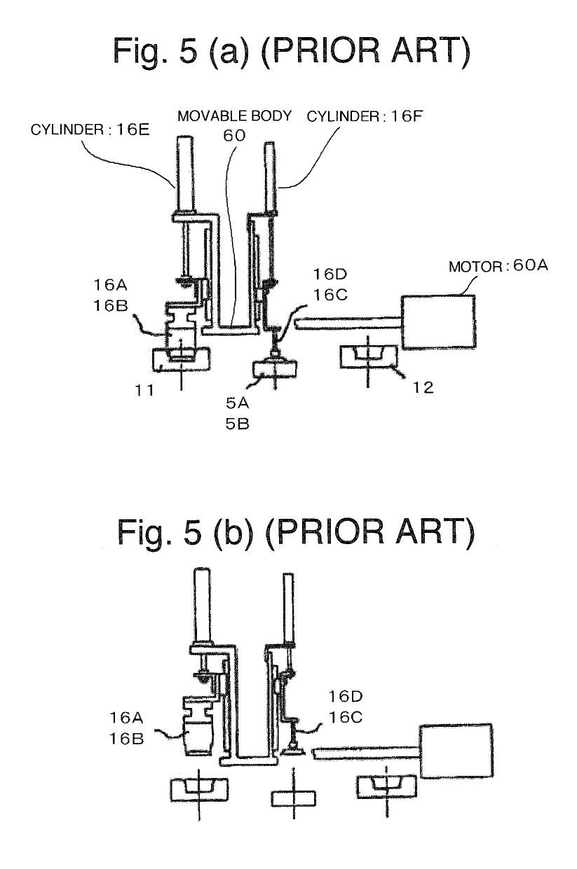

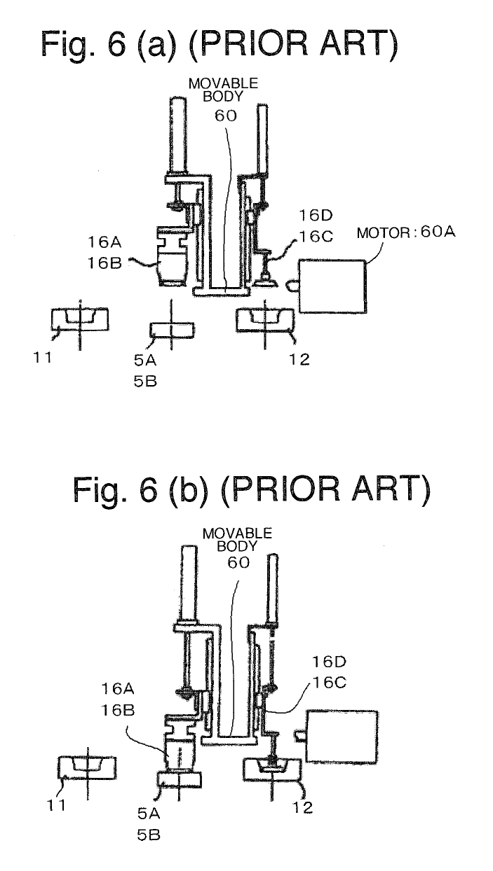

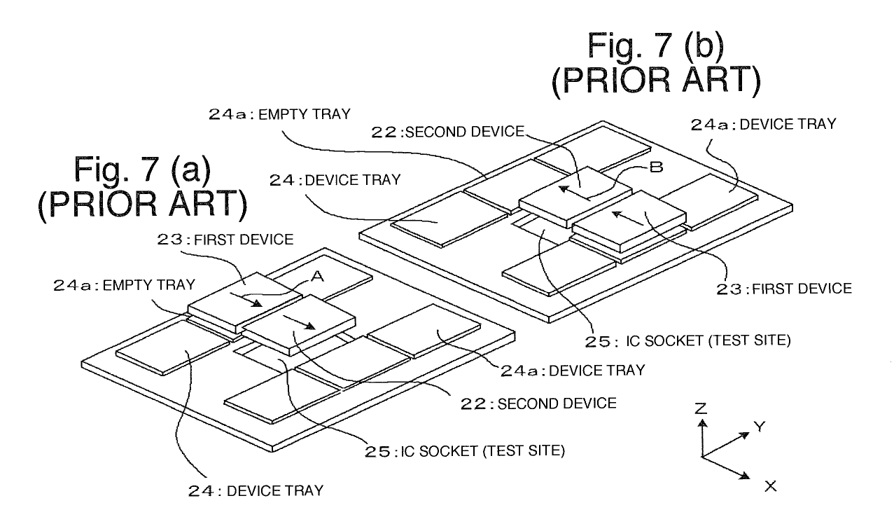

FIG. 2 is a view illustrating movements of the devices held by the respective contact heads of the first and second transfer bodies, shown in FIG. 1, by focusing attention only on the movements of the devices, the first device, and the second device are concurrently shifted in respective directions opposite to each other. As a result, impacts in the respective direction of the movements thereof can be cancelled out, so that swaying of the transfer means can be lessened, and connection with a tester connected to the IC sockets (not shown) will not be adversely affected.

Furthermore, since it need only be sufficient to provide one column of the device trays for supplying the contact heads with the device, and for housing the devices, respectively, the structure of the indexing mechanism can be rendered compact and low in cost.

Now, it is to be pointed out that a specific and preferred embodiment of the invention is simply shown in the present description as above in order to describe the invention and to show an example thereof. For a mechanism (not shown) of the transfer bodies, and shapes (not shown) of contact heads, use can be made of the public known. It is essential only that the invention is made up such that the devices held by the respective contact heads of the two transfer bodies are concurrently shifted in respective directions opposite to each other along the horizontal direction.

Accordingly, it is to be understood that the invention is not limited to the embodiment described as above, and that various changes and modifications may be made in the invention without departing from the spirit and scope thereof.

What is claimed is:

1. A device transfer system comprising:
a transfer means for transferring a device under test, held by a contact head;
a test site for testing electrical characteristics of the device under test; and
an indexing means for intermittently shifting the device under test, placed on a device tray;
wherein the transfer means are made up such that two contact heads are concurrently and horizontally shifted in respective directions opposite to each other.

2. The device transfer system according to claim 1, wherein the two contact heads are made up so as to differ in height from each other, thereby enabling the two contact heads to pass by each other.

3. The device transfer system according to claim 1, wherein the contact heads making up the transfer means are configured so as to shuttle to and fro between the device tray including an empty tray, and a test site disposed in the vicinity of the device tray while passing by each other in the respective directions opposite to each other.
